(19) United States
(12) Patent Application Publication
(10) Pub. No.: US 2010/0124174 A1
(43) Pub. Date: May 20, 2010

(54) COMMUNICATION DEVICE AND LOOPBACK TESTING METHOD

(75) Inventor: Katsumi SHIMADA, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/619,720

(22) Filed: Nov. 17, 2009

(30) Foreign Application Priority Data
Nov. 19, 2008 (JP) 2008-295050

(51) Int. Cl. G01R 31/08

(52) U.S. Cl. 370/249

(57) ABSTRACT

There is provided communication device operable to verify normality of a network by a loopback test, the communication device including a plurality of ports used to connect to a physical link included in the network, and an identification information addition part to add virtual port information used to identify a virtual port to a reply frame when receiving a message frame to the virtual port set on the physical link, the message frame being used to verify normality of the network by the loopback test, and replying the reply frame in which the virtual port information is added, to a communication device that has transmitted the message frame.

### CROSS-REFERENCE TO RELATED APPLICATION

This application is based upon and claims the benefit of priority of the prior Japanese Patent Application No. 2008-295050, filed on Nov. 19, 2008, the entire contents of which are incorporated herein by reference.

### FIELD

The embodiments discussed herein are related to a communication device operable to verify normality of a network by a loopback test and a loopback testing method of the communication device.

### BACKGROUND

In a large scale network, Virtual Local Area Networks (VLANs) which are grouped by section or role in a company have been utilized (see, for example, Japanese Laid-open Patent Publication No. 2003-234750). In VLANs, a group is identified using a VLAN-ID (hereinafter, VID) which is an identification number for identifying a VLAN group.

In layer 2 switches (hereinafter, L2SWs) having the VLAN function, each port is assigned in advance a VLAN group to which the port belongs. Some ports may belong to a plurality of VLAN groups. In this case, 4-byte data called a VLAN tag including a VID is added to a frame transmitted from or received to the port. Thus, VLAN groups are identified frame by frame. L2SWs further have a function for learning a MAC (Media Access Control) address and information for identifying a VLAN group in combination with each other. Such a function is specified in, for example, IEEE 802.1d. L2SWs having the VLAN function have also been utilized in order for a communications carrier to provide a service for interconnecting LANs at a plurality of locations such as between a head office and branches of a certain company. Such a service is called L2VPN (Layer2 Virtual Private Network). In this case, a VID in a VLAN tag is utilized to identify an end user (for example, a company). In an L2VPN service, the virtual port function is used. With the use of the virtual port function, frames belonging to the same VLAN on a single physical link and having different VIDs may be transferred in a mixed state.

FIG. 18 is a diagram illustrating the virtual port function. In FIG. 18, L2SWs 101 to 103 are illustrated. The L2SWs 101 to 103 are, for example, provided by a communications carrier, and set up a carrier network 111. As illustrated in FIG. 18, the L2SW 101 has ports 1 to 3. The port 1 is connected to site 1 of a customer A which is an end user, and the port 3 is connected to site 2 of the same customer A. The port 2 of the L2SW 101 and port 1 of the L2SW 102 belong to the same VLAN group, and are connected to each other via a single physical link 121. The L2SWs 101 and 102 use the virtual port function, and have virtual ports with in-port logical numbers 1 and 2. With the virtual ports, the L2SWs 101 and 102 seem to have two links although they are connected to each other via the single physical link 121. The in-port logical number is used to identify virtual ports in a physical link. Thus, for example, the virtual port with the in-port logical number 1 is assigned the site 1 of the customer A, and the virtual port with the in-port logical number 2 is assigned the site 2 of the customer A. Then, the sites 1 and 2 of the customer A are able to have different band limits or the like.

A communications carrier provides an L2VPN service using a testing method called a loopback test as a method for verifying the normality of an end-to-end connection over a network (see, for example, “Connectivity Fault Management”, IEEE Std 802.1ag-2007, Clause 20.2, Pages 141-142).

As illustrated in FIG. 18, the L2SWs 101 to 103 are connected to a maintenance terminal 131 via a supervisory control network 132. A maintenance person uses the maintenance terminal 131 to set a port of an L2SW which serves as a loopback MEP (Maintenance Entity group end Point; an end point from which a loopback frame is transmitted or received, also called a maintenance function point). For example, it is assumed that the maintenance person has set port 2 of the L2SW 103 and port 3 of the L2SW 102 as MEP. The port 2 of the L2SW 103 is set as an MEP, the L2SW 103 transmits from the port 2, in accordance with an instruction of the maintenance terminal 131, a loopback message (hereinafter, LBM) to the target, namely, the port 3 of the L2SW 102. Upon receipt of the LBM at the port 3 of the L2SW 102, the L2SW 102 copies test data included in the LBM to a loopback reply (hereinafter, LBR), and transmits the LBR to the port 2 of the L2SW 103. The L2SW 103 transmits the LBR received at port 2 to the maintenance terminal 131. And the maintenance terminal 131 compares test data included in the LBM with the test data included in the LBR to verify the normality of the network. If the test data in the LBM and the test data in the LBR match, the maintenance terminal 131 determines that the network between the port 2 of the L2SW 103 and the target, namely, the port 3 of the L2SW 102, is under normal condition.

### SUMMARY

According to an aspect of the embodiment, there is provided communication device operable to verify normality of a network by a loopback test, the communication device including a plurality of ports used to connect to a physical link included in the network, and an identification information addition part to add virtual port information used to identify a virtual port to a reply frame when receiving a message frame to the virtual port set on the physical link, the message frame being used to verify normality of the network by the loopback test, and replying the reply frame in which the virtual port information is added, to a communication device that has transmitted the message frame.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a principle of a communication device;

FIG. 2 is a diagram illustrating an example network configuration in which a communication device according to a first embodiment is applied;

FIG. 3 is a diagram illustrating a VLAN accommodating a customer A of FIG. 2;

FIG. 4 is a diagram illustrating a VLAN accommodating a customer B of FIG. 2;

FIG. 5 is a diagram illustrating virtual ports of L2SWs;

FIG. 6 is a diagram illustrating a block configuration diagram of an L2SW;

FIG. 7 is a diagram illustrating an example data configuration of a VLAN setting table (TB) which is stored in a setting TB memory;

FIG. 8 is a diagram illustrating an example data configuration of an output destination setting table (TB) which is stored in a setting TB memory;

FIG. 9 is a diagram illustrating an example data configuration of a learning table (TB) which is stored in a learning TB memory;

FIG. 10 is a diagram illustrating a frame header used in a device (in-device frame header);

FIG. 11 is a diagram illustrating a frame format of an LBM and an LBR;

FIG. 12 is a diagram illustrating an exemplary screen obtained as a result of loopback test 1, which is displayed on a maintenance terminal;

FIG. 13 is a diagram illustrating an exemplary screen obtained as a result of loopback test 3, which is displayed on a maintenance terminal;

FIGS. 14A to 14B are flowcharts illustrating the operation of a packet SW unit;

FIG. 15 is a flowchart illustrating the operation of a packet SW unit;

FIG. 16 is a flowchart illustrating the operation of a packet SW unit according to a second embodiment;

FIG. 17 is a flowchart illustrating the operation of a packet SW unit according to the second embodiment; and

FIG. 18 is a diagram illustrating a virtual port function.

### DESCRIPTION OF EMBODIMENTS

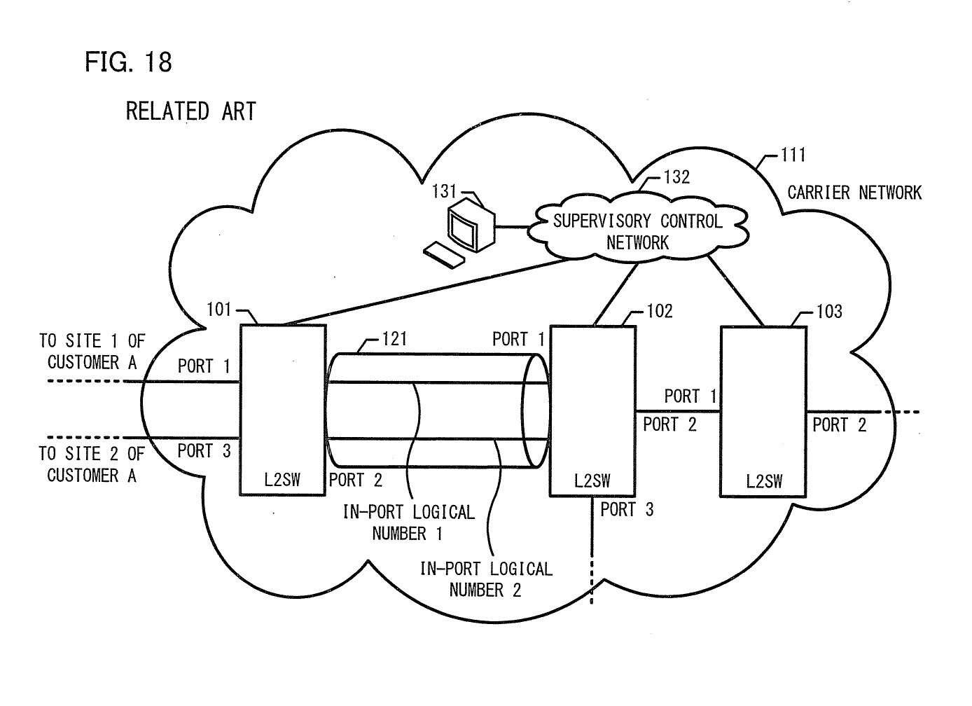

A loopback test in which a virtual port is set to an MEP (Maintenance Entity group end Point) will be described. For example, in FIG. 18, it is assumed that the maintenance person performs a loopback test in which an MEP is set in the port 2 of the L2SW 103 and in which the port 1 of the L2SW 102 is set as the target. The source MAC address of the LBM transmitted from the L2SW 103 is the address of the port 2 of the L2SW 103.

Upon receipt of the LBM (loopback message) for the port 2 of the L2SW 102, the L2SW 102 refers to a learning table on the basis of the destination MAC address. When the MAC address has not been learned, the L2SW 102 floods the LBM to the in-port logical numbers 1 and 2 of the port 1 of the L2SW 102. When the MAC address has been learned, on the other hand, the LBM is transmitted to only the corresponding one of the in-port logical numbers 1 and 2. The in-port logical number is used to identify virtual ports in a physical link.

Upon receipt of the LBM for the in-port logical numbers 1 and 2 of the port 1 of the L2SW 102, the L2SW 102 transmit an LBR (loopback reply) to the port 2 of the L2SW 103 as the destination because the destination MAC addresses of the LBM match.

Here, as a result of the reference to the learning table by the port 2 of the L2SW 102, when the destination MAC address has not been learned, as described above, the LBM is flooded to the in-port logical numbers 1 and 2, and therefore an LBR is transmitted from each of the in-port logical numbers 1 and 2. As a result of the reference to the learning table by the port 2 of the L2SW 102, when the destination MAC address has been learned, on the other hand, as described above, the LBM is transferred to one of the in-port logical numbers 1 and 2, and therefore an LBR is transmitted from the one of the in-port logical numbers 1 and 2.

That is, the number of LBR responses changes depending on the learning state of the MAC address in the L2SW 102, and the maintenance person cannot correctly verify the normality of the network. Further, it is assumed that the maintenance person performs a loopback test in which an MEP is set in the in-port logical number 1 of the port 1 of the L2SW 102 and in which the port 2 of the L2SW 103 is set as the target. The source MAC address of the LBM transmitted from the L2SW 102 is the address of the port 1 of the L2SW 102.

Upon receipt of the LBM for the port 2 of the L2SW 102 from the port 1 (the virtual port with the in-port logical number 1), the L2SW 102 learns the source MAC address on the basis of the received LBM. At this time, the L2SW 102 also learns the in-port logical number correspond to the port 2, that is, the MAC address, the port number and the in-port logical number of the port 1 of the L2SW 102 are stored in association with each other.

When the LBM reaches the port 2, the L2SW 103 sets the MAC address of the port 1 of the L2SW 102 in the destination MAC address of the LBR, and transmits the LBR to the L2SW 102. At this time, the L2SW 103 copies test data included in the received LBM to the LBR.

Upon receipt of the LBR for the port 2 of the L2SW 102, the L2SW 102 refers to the learning table on the basis of the destination MAC address included in the LBR. As described previously, the L2SW 102 has learned the in-port logical number 1 of the L2SW 102, and therefore transfers the LBR to the in-port logical number 1 as the destination. Thus, the LBR reaches the in-port logical number 1 from which the LBM has been transmitted, and the loopback test is succeeded.

Here, it is assumed that during the performance of the loopback test described above, another maintenance person has performed a loopback test in which an MEP is set in the in-port logical number 2 of the L2SW 102.

When an LBM reaches the port 2 of the L2SW 102, the L2SW 102 learns the source MAC address in a manner similar to that described above. As a result, the learning content of the in-port logical number 1, which has been learned in the manner described above, is overwritten with the content of the in-port logical number 2. Thus, even if the LBR for the port 2 of the L2SW 102 of the previously performed loopback test is received, the L2SW 102 does not transfer the LBR to the in-port logical number 1 but transfers the LBR to the in-port logical number 2.

That is, the previous loopback test in which the in-port logical number 1 of the L2SW 102 is set as an MEP has failed and the normality of the network is not correctly verified.

Preferred embodiments will be explained with reference to accompanying drawings.

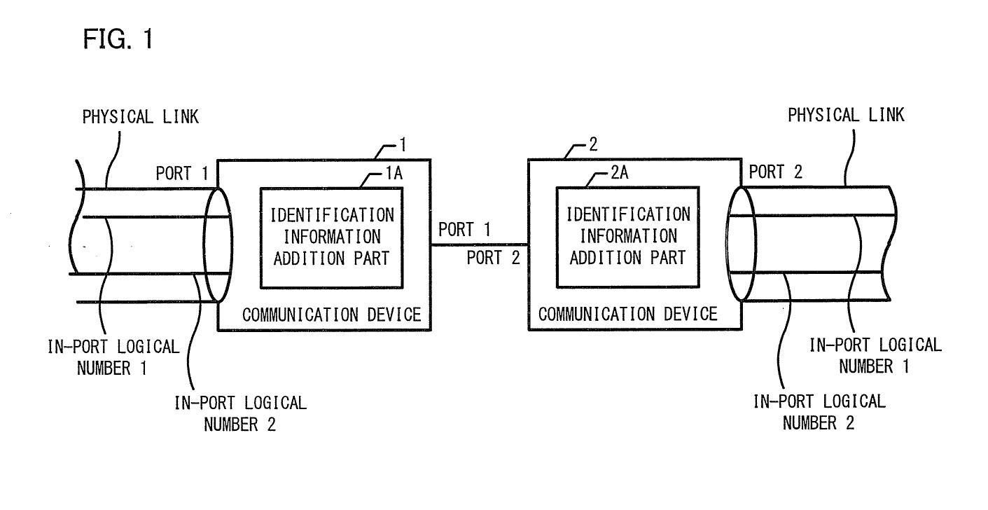

FIG. 1 is a diagram illustrating a principle of a communication device. As illustrated in FIG. 1, communication devices 1 and 2 have identification information addition parts 1a and 2a, respectively. The communication devices 1 and 2 are connected to each other via port 2 of the communication device 1 and port 1 of the communication device 2. A single physical link is connected to port 1 of the communication device 1, and virtual ports with in-port logical numbers 1 and 2 are set on this physical link. A single physical link is connected to port 2 of the communication device 2, and virtual ports with in-port logical numbers 1 and 2 are set on this physical link. The communication devices 1 and 2 set up a VLAN network.

When a message frame for verifying the normality of the VLAN network is received at the virtual ports with the in-port logical numbers 1 and 2 and a reply frame is returned to the communication device 2 that has transmitted the message frame, the identification information addition means 1A of the communication device 1 adds virtual port information for identifying the virtual ports to the reply frame. For example, when the message frame is received at the virtual port with the in-port logical number 1, the identification information addition means 1A adds the in-port logical number ‘1’ to the reply frame, and returns the reply frame to the communication device 2. Further, when the message frame is received at the virtual port with the in-port logical number 2, the identification information addition means 1A adds the in-port logical number ‘2 ’ to the reply frame, and returns the reply frame to the communication device 2. Thus, the communication device 2 that has transmitted the message frame for verifying the normality of the network recognizes from where the reply frame has been returned based on a level of the virtual port corresponding to the in-port logical number. That is, the maintenance person may correctly verify the normality of the network.

When a message frame for verifying the normality of the VLAN network is transmitted using the virtual ports with the in-port logical numbers 1 and 2 as the start points, the identification information addition part 2A of the communication device 2 adds virtual portion information for identifying the virtual ports to the message frame. For example, when a message frame is transmitted using the virtual port with the in-port logical number 1 as the start point, the identification information addition part 2A adds the in-port logical number ‘1 ’ to the message frame and transmits the message frame to the communication device 1. Further, when a message frame is transmitted using the virtual port with the in-port logical number 2 as the start point, the identification information addition part 2A adds the in-port logical number ‘2 ’ to the message frame, and transmits the message frame to the communication device 1.

Here, it is assumed that the identification information addition part 1A of the communication device 1 copies the virtual port information included in the received message frame to the reply frame and returns the reply frame to the communication device 2. It is also assumed that when the reply frame received at the port 1 of the communication device 2 includes virtual port information, the communication device 2 transfers the received reply frame to the virtual port used as the transmission start point of the message frame on the basis of the virtual port information included in the reply frame without referring to the learning table of the MAC address. In this case, the port 1 of the communication device 2 may correctly transfer the received reply frame to the virtual port used as the transmission start point of the message frame even if the learning table of the MAC address has been overwritten due to the loopback test performed by another maintenance person.

That is, the identification information addition part 2A adds the virtual port information about the virtual port used as the start point of the message frame to the message frame and transmits the message frame. Thereby the communication device 2 that receives the reply frame may correctly transfer the reply frame to the virtual port used as the start point of the message frame even if the table of the MAC address has been overwritten. Accordingly, the maintenance person may correctly verify the normality of the network.

### First Embodiment

A first embodiment will be explained in detail with reference to the drawings.

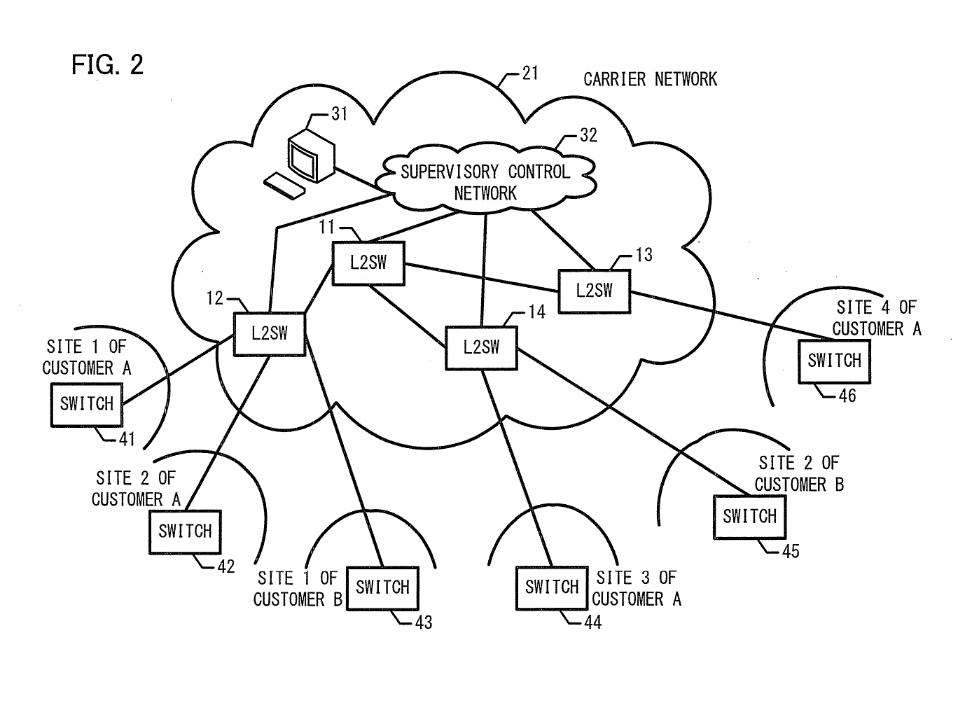

FIG. 2 is a diagram illustrating an example network configuration in which a communication device according to the first embodiment is applied. The L2SWs 11 to 14 are L2SWs provided by a communications carrier, and set up a carrier network 21. The maintenance terminal 31 is connected to the L2SWs 11 to 14 via the supervisory control network 32. Switches 41, 42, 44 and 46 represent switches provided in sites 1 to 4 of a customer A, respectively, and switches 43 and 45 represent switches provided in sites 1 and 2 of a customer B, respectively. Although not illustrated in FIG. 2, end stations exist under the switches 41 to 46.

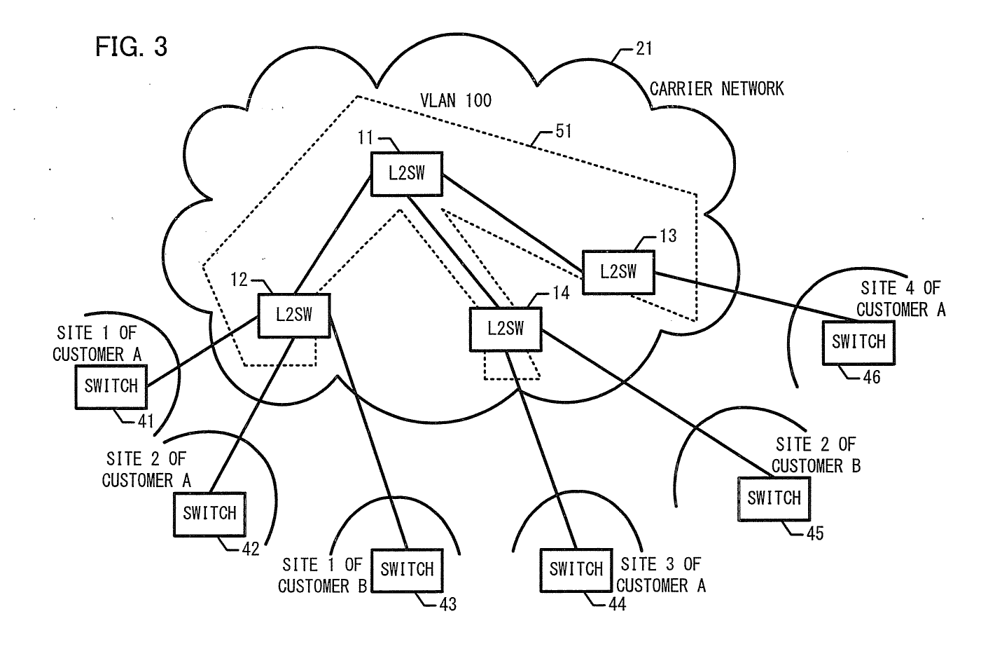

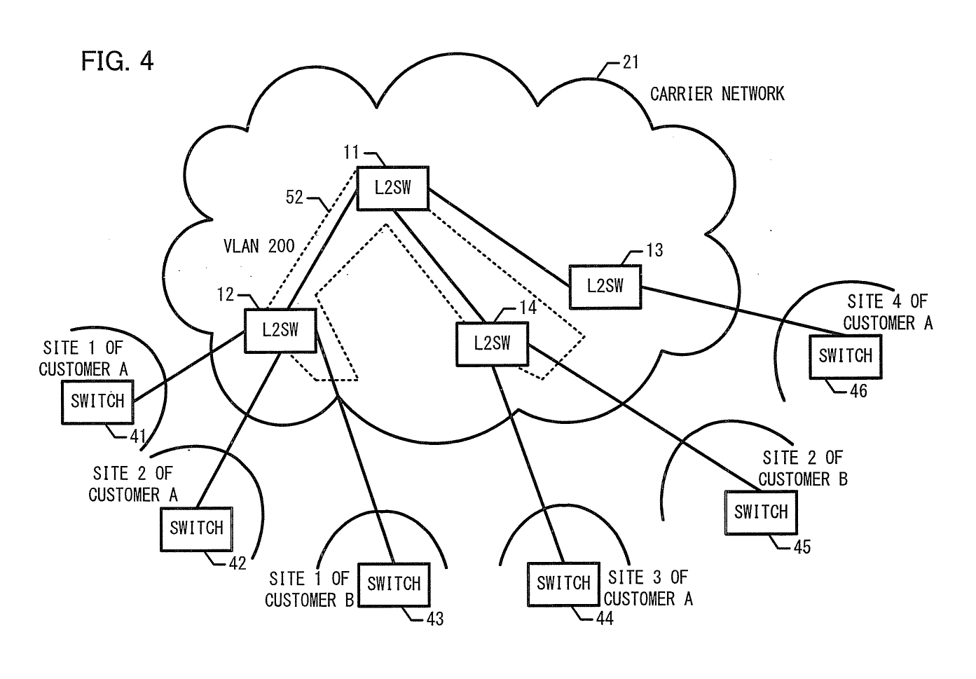

FIG. 3 is a diagram illustrating a VLAN accommodating the customer A of FIG. 2. FIG. 4 is a diagram illustrating a VLAN accommodating the customer B of FIG. 2. In FIGS. 3 and 4, the same portions as those in FIG. 2 are assigned the same numerals and explanations thereof are omitted. Note that in FIGS. 3 and 4, the maintenance terminal 31 and supervisory control network 32 of FIG. 2 are omitted.

In VLANs, it is possible to set groups in a virtual manner independently of the physical connection form. For example, as illustrated in a dotted line frame 51 of FIG. 3, the group of the customer A (the sites 1 to 4 of the customer A) illustrated in FIG. 2 is set as a group of a VLAN 100 in a virtual manner independently of the physical connection form. Further, as illustrated in a dotted line frame 52 of FIG. 4, the group of the customer B (the sites 1 and 2 of the customer B) illustrated in FIG. 2 is set as a group of a VLAN 200 in a virtual manner independently of the physical connection form. In a link where data of the plurality of customers A and B is transferred, such as that between the L2SWs 11 and 12, VIDs which are different from each other, for example, VID 100 and VID 200 are added to frames, thereby allowing the customers A and B to be distinguished from each other.

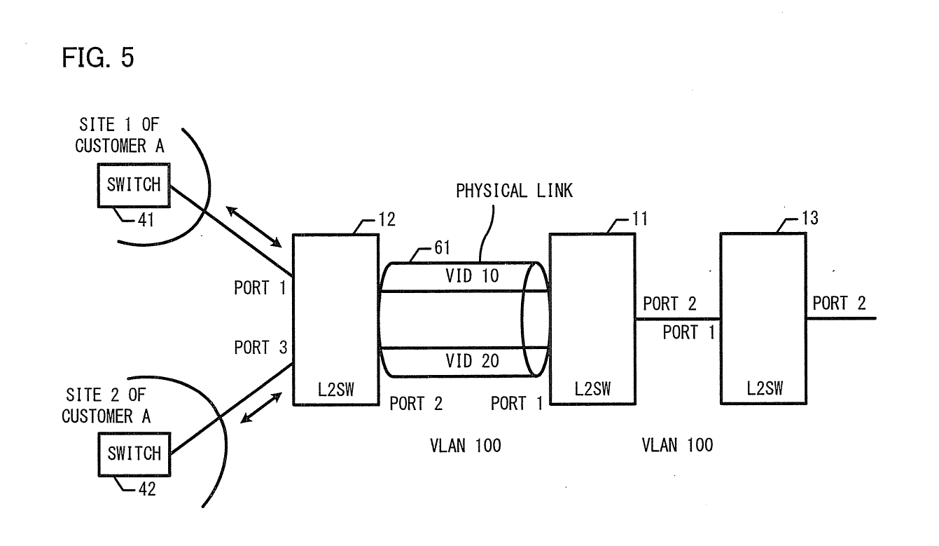

FIG. 5 is a diagram illustrating virtual ports of L2SWs. In FIG. 5, the L2SWs 11 to 13, the switch 41 at the site 1 of the customer A, and the switch 42 at the site 2 of the customer A illustrated in FIG. 2 are illustrated. As illustrated in FIG. 5, port 1 of the L2SW 12 is connected to the switch 41 at the site 1 of the customer A. Port 3 of the L2SW 12 is connected to the switch 42 at the site 2 of the customer A. Port 2 of the L2SW 12 is connected to port 1 of the L2SW 11. The port 2 of the L2SW 12 and the port 1 of the L2SW 11 are connected to each other via a single physical link 61. Port 2 of the L2SW 11 is connected to port 1 of the L2SW 13. Note that other ports of the L2SWs 11 to 13 are not illustrated in FIG. 5.

Since frames transferred at the sites 1 and 2 of the customer A belong to the same group of the VLAN 100, the L2SWs 11 and 12 cannot distinguish them from each other. Thus, individual band limits cannot be set at the site 1 and site 2 of the customer A. Therefore, the L2SWs 11 and 12 include the virtual port function and have virtual ports with in-port logical numbers 1 and 2. At the virtual port with the in-port logical number 1, a VID 10 is added to a frame, and a frame at the site 1 of the customer A is transmitted or received. Further, at the virtual port with the in-port logical number 2, a VID 20 is added to a frame, and a frame at the site 2 of the customer A is transmitted or received. Therefore, the L2SWs 11 and 12 have independent band limits at the sites 1 and 2 of the customer A even if they are connected to each other via the single physical link 61.

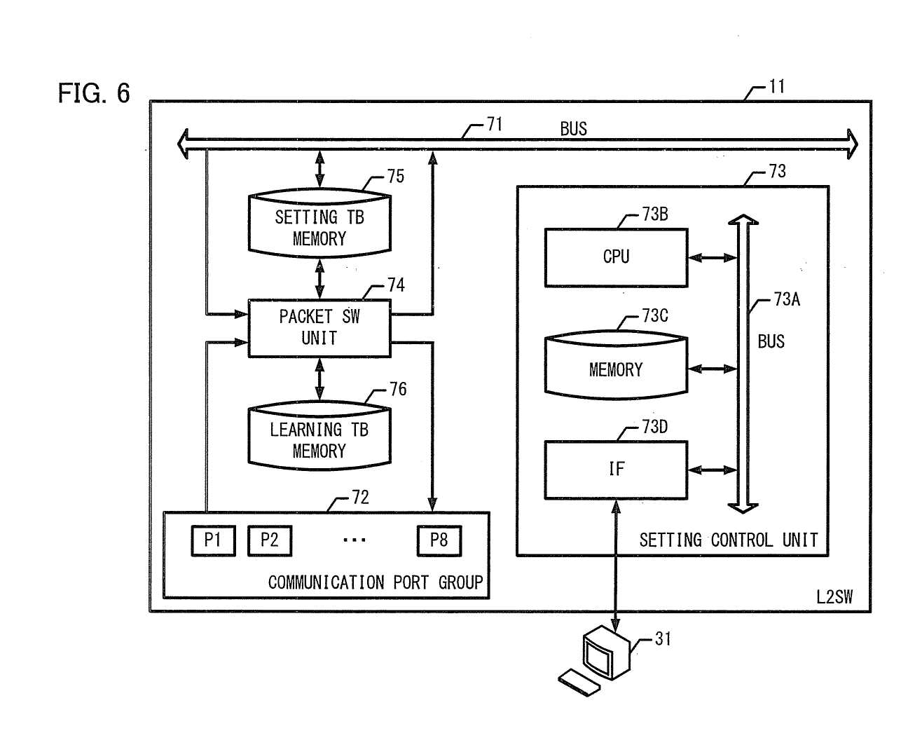

FIG. 6 is a diagram illustrating a block configuration diagram of an L2SW. As illustrated in FIG. 6, the L2SW 11 includes a bus 71, a communication port group 72, a setting control unit 73, a packet SW (SW: switch) unit 74, a setting TB (TB: table) memory 75, and a learning TB memory 76. The setting control unit 73 includes a bus 73A, a CPU (Central Processing Unit) 73B, a memory 73C, and an IF (communication interface) 73D. In FIG. 6, the maintenance terminal 31 illustrated in FIG. 2 is also illustrated. The L2SWs 12 to 14 illustrated in FIG. 2 also have a block configuration similar to that of FIG. 6, and explanations thereof are omitted.

The setting control unit 73, the packet SW unit 74, and the setting TB memory 75 are connected to the bus 71.

The communication port group 72 is composed of a plurality of ports P1 to P8. While the number of ports P1 to P8 changes depending on the device size of the L2SW, an L2SW having the learning function generally has three or more ports. The individual ports P1 to P8 may be connected to a single physical link. Note that the ports P1 and P2 correspond to the ports 1 and 2 of the L2SW 11 illustrated in FIG. 5.

The setting control unit 73 controls the overall L2SW 11. The CPU 73B, the memory 73C, and the IF 73D are connected to the bus 73A of the setting control unit 73. The CPU 73B executes a program to thereby control the overall L2SW 11. The CPU 73B generates an LBM or an LBR in accordance with a command from a maintenance person. The memory 73C has stored therein the program executed by the CPU 73B. The IF 73D receives a command transmitted from the maintenance terminal 31 operated by the maintenance person, and notifies the CPU 73B of the reception of the command. The IF 73D also transmits a result of executing the command to the maintenance terminal 31.

Upon receipt of a frame from one of the communication port group 72 and the bus 71, the packet SW unit 74 learns the source MAC address on the basis of the port number of the receiving port, SA (Source Address) in the frame, the VLAN information, and the like, which are added to the frame. The packet SW unit 74 stores the learning content in the learning TB memory 76. Further, the packet SW unit 74 refers to one of the type of the received frame and the learning TB memory 76 to determine the transfer destination of the received frame. At this time, the packet SW unit 74 adds information about the output destination port to the frame to be transferred, and outputs the frame to the port of the communication port group 72. Further, upon receipt of a frame (LBM) to be received by the L2SW 11 itself, the packet SW unit 74 transmits the frame to the setting control unit 73 via the bus 71. The setting control unit 73 generates a reply frame (LBR) or transmits a loopback test result to the maintenance terminal 31 in accordance with the content of the received frame.

The setting TB memory 75 has a plurality of tables stored therein. For example, a port-based VLAN setting table and a VLAN-based output destination setting table are stored.

The learning TB memory 76 stores the content of a learned MAC address. For example, the learning TB memory 76 has stored therein the source MAC address of a previously received frame, the communication port which the frame has reached, VLAN information, and the like in association with each other. The learning TB memory 76 is updated at any time by the packet SW unit 74.

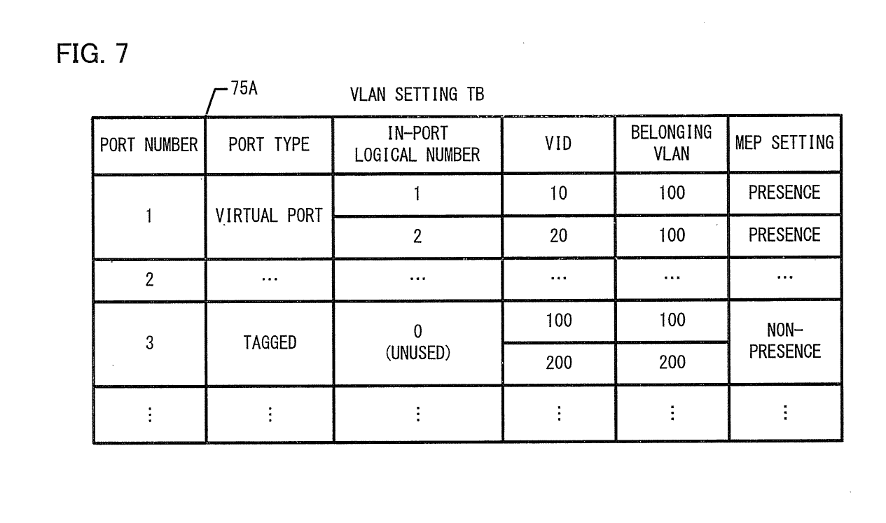

FIG. 7 is a diagram illustrating an example data configuration of a VLAN setting TB which is stored in a setting TB memory. As illustrated in FIG. 7, the setting TB memory 75 has stored therein a VLAN setting TB 75A representing VLAN settings for individual ports. The VLAN setting TB 75A has sections of port number, port type, in-port logical number, VID, belonging VLAN, and MEP setting.

In the section of port number, the port numbers of the ports P1, P2, . . . of the communication port group 72 are stored. Port numbers 1, 2, . . . correspond to the ports P1, P2, . . . of the communication port group 72, respectively.

In the section of port type, the port types of the ports P1, P2, . . . are stored. For example, types of virtual port and Tagged are stored.

In the section of in-port logical number, when the ports P1, P2, . . . are virtual ports, the in-port logical numbers of the virtual ports are stored. When the ports P1, P2, . . . are not virtual ports, ‘0 ’ is stored.

In the section of VID, VIDs to be added to frames transmitted or received from the ports P1, P2, . . . are stored.

In the section of belonging VLAN, the groups of VLANs to which the ports P1, P2, . . . belong are stored. For example, as explained in FIGS. 3 and 4, the customer A belongs to the group of the VLAN 100, and the customer B belongs to the VLAN 200. Therefore, the VLAN to which a port where a frame of the customer A is transmitted or received belongs is set to ‘100 ’, and the VLAN to which a port where a frame of the customer B is transmitted or received belongs is set to ‘200’. Further, the VLAN to which a port where frames of the customers A and B are transmitted or received belongs is set to ‘100 ’ and ‘200’.

In the section of MEP setting, MEP setting information is stored. For example, when an MEP is set in a certain port, information indicating ‘presence’ is stored in the section of MEP setting associated with the port. Further, when no MEP is set in a certain port, information indicating ‘non-presence’ is stored in the section of MEP setting associated with the port. The MEP setting is set at up to the virtual port by the maintenance terminal 31.

For example, in the example of FIG. 5, the port 1 of the L2SW 11 has two virtual ports. The in-port logical numbers of the two virtual ports are ‘1 ’ and ‘2 ’. The VID of the in-port logical number 1 is ‘10 ’, and the VID of the in-port logical number 2 is ‘20 ’. Further, data of the customer A is transmitted or received from the port 1 of the L2SW 11, and the VLAN to which the port 1 of the L2SW 11 belongs is the VLAN 100. Therefore, the VLAN setting TB 75A of the port 1 of the L2SW 11 is as indicated by the horizontal section associated with port number ‘1 ’ in FIG. 7. When the MEP setting is made to each of the in-port logical numbers 1 and 2 of the port 1, the section of MEP setting is set to ‘presence’ as illustrated in FIG. 7.

Further, although not illustrated in FIG. 5, it is assumed that the port 3 of the L2SW 11 is connected to the L2SW 14 illustrated in FIG. 2. It is assumed that the port 3 of the L2SW 11 has the Tagged type. In this case, in the horizontal section associated with port number ‘3 ’ in FIG. 7, the port type is set to Tagged and the in-port logical number is set to ‘0 ’ (unused). Further, since the sites of the customers A and B are connected under the L2SW 14 connected to the port 3, the VID is set to ‘100 ’ and ‘200 ’. Further, the belonging VLAN is also set to ‘100 ’ and ‘200 ’. When no MEP is set in the port 3, the section of MEP setting is set to ‘non-presence’ as illustrated in FIG. 7. Note that a VLAN tag is added to a frame to be transmitted to or received from a port with “Tagged”.

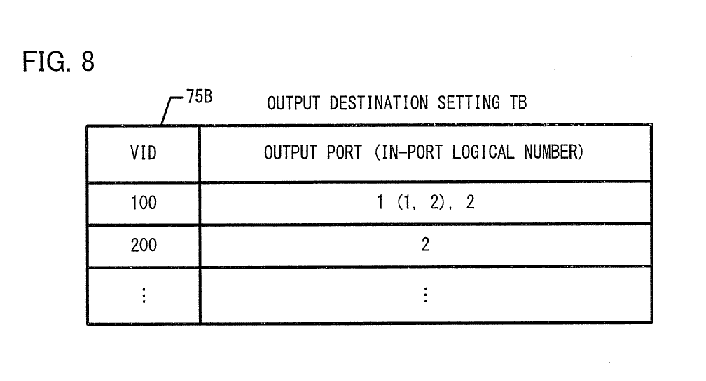

FIG. 8 is a diagram illustrating an example data configuration of an output destination setting table (TB) which is stored in a setting TB memory. As illustrated in FIG. 8, the setting TB memory 75 has stored therein an output destination setting TB 75B representing the frame output destinations for individual VLANs. The output destination setting TB 75B has sections of VID and output port.

In the section of VID, a VID added to a frame is stored. In the section of output port, the port number of a port to which a frame is output is stored. Note that numbers in brackets represent in-port logical numbers.

The output destination setting TB 75B is used for determining an output destination port corresponding to a VLAN when the MAC address has not been learned or when a frame is flooded.

For example, it is assumed that the L2SW 11 has received a frame with VID 100 at the port 2. When the MAC address of the received frame has not yet been learned, the L2SW 11 refers to the output destination setting TB 75B, and outputs the received frame to the port 1 (including the virtual ports with the in-port logical numbers 1 and 2), except for the port 2 where the frame has been received. Further, it is assumed that the L2SW 11 has received a multicast frame with VID 100 at the port 2. The L2SW 11 refers to the output destination setting TB 75B, and outputs the received frame to the port 1 (including the virtual ports with the in-port logical numbers 1 and 2), except for the port 2 where the frame has been received.

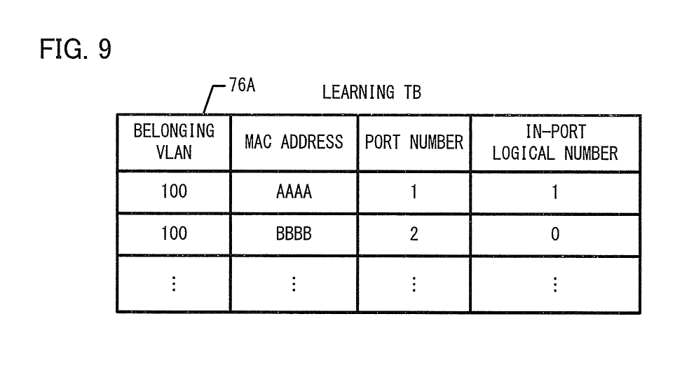

FIG. 9 is a diagram illustrating an example data configuration of a learning table (TB) which is stored in a learning TB memory. As illustrated in FIG. 9, a learning TB 76A has sections of belonging VLAN, MAC address, port number, and in-port logical number, and stores them in association with each other. In the section of belonging VLAN, a group of a VLAN to which a learned MAC address belongs is stored. In the section of MAC address, a learned MAC address is stored. In the section of port number, a port number where a frame of a learned MAC address has been received is stored. In the section of in-port logical number, an in-port logical number where a frame of a learned MAC address has been received is stored.

For example, it is assumed that the L2SW 11 has received a frame with source MAC address ‘aaaa’ from the virtual port with the in-port logical number 1 of the port 1. In this case, the L2SW 11 refers to the VLAN setting TB 75A to acquire that the received frame belongs to the VLAN 100, and stores ‘100’ in the section of belonging VLAN of the learning TB 76Aa. Further, the source MAC address ‘aaaa’ of the received frame is stored in the section of MAC address. Further, ‘1 ’ is stored in the section of port number and the section of in-port logical number.

Thus, for example, upon receipt of a frame with destination MAC address ‘aaaa’, the packet SW unit 74 refers to the learning TB 76A and may recognize that the received frame is to be transferred to the port that is assigned the port number 1 and that is the virtual port with the in-port logical number 1. Further, the packet SW unit 74 refers to the VLAN setting TB 75A on the basis of the belonging VLAN 100, the port number 1, and the in-port logical number 1, which are obtained by referring to the learning TB 76A, so that ‘10 ’ may be added to the VID of the frame to be transferred.

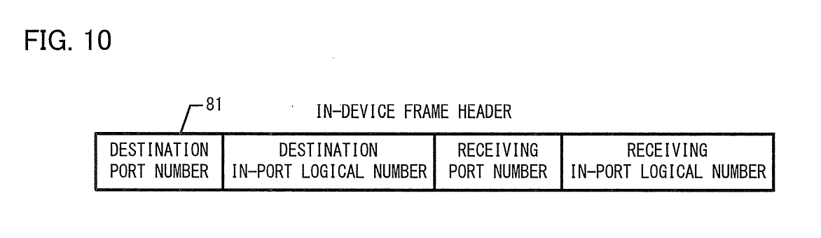

FIG. 10 is a diagram illustrating a frame header used in a device (in-device frame header). In the L2SW 11, an in-device frame header 81 illustrated in FIG. 10 is added to a frame. The in-device frame header 81 has areas where a destination port number, a destination in-port logical number, a receiving port number, and a receiving in-port logical number are set. In the area of destination port number, the port number of a port to which a frame is to be output is set. In the area of destination in-port logical number, the in-port logical number of a virtual port to which a frame is to be output is set. In the area of receiving port number, the port number of a port where a frame has been received is set. In the area of receiving in-port logical number, the in-port logical number of a virtual port where a frame has been received is set.

For example, it is assumed that the communication port group 72 has received a frame at the virtual port with the in-port logical number 1 of the port P1. In this case, for the port P1, ‘1 ’ is set in each of the areas of the receiving port number and receiving in-port logical number in the in-device frame header 81.

Note that when the port where a frame has been received is not a virtual port, ‘0 ’ is set in the area of receiving in-port logical number.

A frame received at the port P1 is added with the in-device frame header 81 described above, and is output to the packet SW unit 74. The packet SW unit 74 refers to the learning TB 76A, and acquires the port number and in-port logical number to which the received frame is to be output. The packet SW unit 74 sets the acquired port number and in-port logical number in the areas of the destination port number and the destination in-port logical number in the in-device frame header 81, and outputs the received frame to the communication port group 72. Note that when the acquired port is not a virtual port, ‘0 ’ is set in the area of destination in-port logical number.

The frame received from the packet SW unit 74 is output from the port P1, P2, . . . where the frame is to be output. In this way, the frame is transferred to the desired destination.

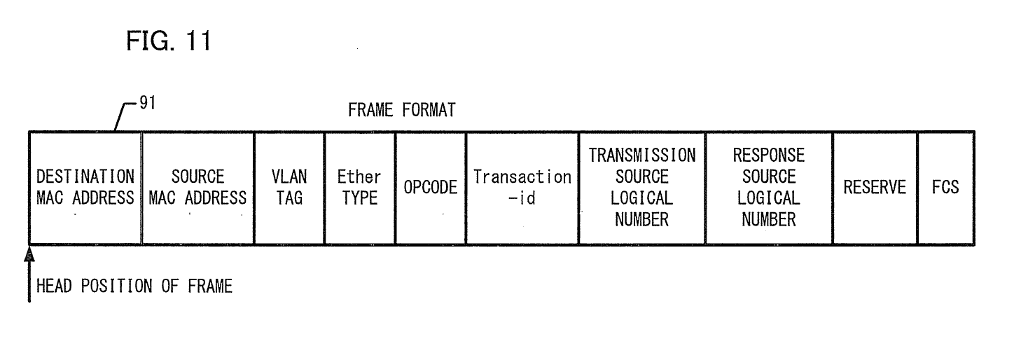

FIG. 11 is a diagram illustrating a frame format of an LBM and an LBR. The L2SWs 11 to 14 illustrated in FIG. 2 generate an LBM having a frame format 91 illustrated in FIG. 11 and transmit the LBM to the target in accordance with an instruction of the maintenance terminal 31. Further, upon receipt of the LBM, the target L2SWs 11 to 14 generate an LBR having the frame format 91 illustrated in FIG. 11, and transmits the LBR to the L2SWs 11 to 14 that have transmitted the LBM. The frame format 91 has areas where a destination MAC address, a source MAC address, a VLAN tag, an Ether type, an operation code (opcode), a Transaction-id, a transmission source logical number, response source logical number, a reserved area, and an FCS are set.

In the area of destination MAC address, the MAC address of a port to which the LBM or LBR is transmitted is set. In the area of source MAC address, the MAC address of the port of the own device is set. In the area of VLAN tag, the VLAN value of the transmission source where an MEP is set is set. In the area of Ether Type, a value indicating that the frame is an Ether Type used for OAM (Operations, Administration, and Maintenance) is set. In the area of opcode, a value indicating that the frame is an LBM or an LBR is set. When the frame is an LBM, ‘0x03 is set. When the frame is an LBR, ‘0x02 ’ is set. In the area of Transaction-id, an arbitrary value is set. The Transaction-id is used for verifying the normality of the LBR at the transmission source MEP. In the area of transmission source logical number, when the frame is an LBM, the in-port logical number of the virtual port, which is the transmission source of the LBM, is set. When the port of the transmission source of the LBM is not a virtual port, ‘0 ’ is set. Further, in the area of transmission source logical number, when the frame is an LBR, the transmission source logical number of the LBM is copied and set. In the area of response source logical number, when the frame is an LBM, the in-port logical number of the virtual port set to the target is set. When the target is not a virtual port, ‘0 ’ is set. Further, in the area of response source logical number, when the frame is an LBR and when the port, which is the transmission source of the LBR, is a virtual port, the in-port logical number thereof is set. When the transmission source of the LBR is not a virtual port, ‘0 ’ is set. In the area of FCS (Frame Check Sequence), data for checking the normality of the frame is set.

In the following, four examples of loopback tests will be explained with reference to FIG. 5.

### Loopback Test 1

It is assumed that a maintenance person performs a multicast loopback test in which the port 2 of the L2SW 13 to which the VLAN 100 is assigned is set as the start point of MEP.

In this case, the setting control unit 73 of the L2SW 13 sets a multicast MAC address in the area of destination MAC address in the frame format 91 illustrated in FIG. 11. In the area of source MAC address, the MAC address of the port 2 of the L2SW 13 is set. In the area of VLAN tag, ‘100 ’ is set. In the area of Ether Type, a value indicating that the frame is an Ether Type for OAM is set. In the area of opcode, ‘0x03 ’ is set because of an LBM. In the area of Transaction-id, an arbitrary value specified by the maintenance person is set. In the area of transmission source logical number, ‘0 ’ is set because the port 2 of the L2SW 13 is not a virtual port. In the area of response source logical number, ‘0 ’ is set because no virtual port is specified as the target by the multicast loopback test. In the area of FCS, data for checking the normality of the frame is set. The L2SW 13 transmits the thus generated LBM via multicast.

It is assumed that the LBM transmitted via multicast has been received at the port 2 of the L2SW 11. The L2SW 11 adds the in-device frame header 81 to the received LBM. At this time, the L2SW 11 sets the port number ‘2 ’ of the port 2 in the area of receiving port number in the in-device frame header 81. Since the port 2 is not a virtual port, ‘0 ’ is set in the receiving in-port logical number.

The LBM with the in-device frame header 81 added thereto is output to the packet SW unit 74. The packet SW unit 74 stores the belonging VLAN, the MAC address, the port number, and the in-port logical number in the learning TB 76A on the basis of the received LBM.

The packet SW unit 74 refers to the VLAN setting TB 75A on the basis of the receiving port number in the in-device frame header 81, and searches for the presence of the section corresponding to the VID of the received LBM. When the corresponding section is not present, the packet SW unit 74 discards the received LBM. Here, it is assumed that the received LBM is not discarded.

Since the destination MAC address of the received LBM is a multicast address, the packet SW unit 74 refers to the output destination setting TB 75B on the basis of the VID 100 of the received LBM, and acquires the output port to which the received LBM is to be output. Referring to FIG. 8, for example, the output ports to which the received LBM is to be output are the port 1 (the in-port logical numbers 1 and 2) and the port 2. The port 2 is the port where the LBM has been received and is therefore excluded.

That is, the output destinations of the LBM received at the port 2 are the in-port logical numbers 1 and 2 of the port 1, and the packet SW unit 74 generates two output frames. Specifically, the packet SW unit 74 generates an output frame (LBM) in which ‘1 ’ is set in each of the areas of destination port number and destination in-port logical number in the in-device frame header 81 on the basis of the output port number acquired by referring to the output destination setting TB 75B. The packet SW unit 74 also generates an output frame (LBM) in which ‘1 ’ and ‘2 ’ are set in each of the areas of destination port number and destination in-port logical number in the in-device frame header 81 on the basis of the output port number acquired by referring to the output destination setting TB 75B.

The packet SW unit 74 refers to the VLAN setting TB 75A on the basis of the destination port number and destination in-port logical number in the in-device frame header 81 of the generated output frames, and acquires information about the VIDs and the MEP settings.

In the above example, each of the destination port number and destination in-port logical number of one of the output frames is ‘1 ’. Each of the destination port number and destination in-port logical number of the other output frame is ‘1 ’ and ‘2 ’. Therefore, referring to FIG. 7, the packet SW unit 74 acquires information indicating VIDs ‘10 ’ and ‘20 ’, and the ‘presence’ of MEP setting.

The packet SW unit 74 determines whether a port to which an output frame is to be output has an MEP setting and whether the output frame is an LBM destined to the own port. In the above example, the ports to which the two output frames are to be output are the in-port logical numbers 1 and 2 of the port 1, and each have an MEP setting. Further, the received LBM is assigned a multicast address and is therefore destined to the own port. In this case, therefore, the packet SW unit 74 determines that an LBM destined to the own port where an MEP has been set has been received. When it is determined that an LBM destined to the own port has been received, the packet SW unit 74 outputs an output frame to the setting control unit 73.

The setting control unit 73 generates an LBR on the basis of the output frame from the packet SW unit 74. In the above example, the setting control unit 73 receives two output frames from the packet SW unit 74 and generates two LBRs having the response source logical numbers 1 and 2.

In the area of destination MAC address of the two LBRs, the source MAC address of the received LBM (the MAC address of the port 2 of the L2SW 13) is set. In the area of source MAC address, the MAC address of the port 1 of the L2SW 11 is set. In the area of VLAN tag, ‘100 ’ is set. In the area of Ether Type, a value indicating that the frame is an Ether Type for OAM is set. In the area of opcode, ‘0x02 ’ is set because of an LBR. In the area of Transaction-id, a copy of the value in the area of Transaction-id of the received LBM is set. In the area of transmission source logical number, a copy of the transmission source logical number 0 of the received LBM is set. In the area of FCS, data for checking the normality of the frame is set. The port number ‘2 ’ where the LBM has been received is set in the destination port number in the in-device frame header 81 of the LBR.

The setting control unit 73 outputs a generated LBR to the packet SW unit 74, and the packet SW unit 74 outputs the LBR to the communication port group 72.

In the above example, two LBRs (response source logical numbers 1 and 2) are output from the port 2 in the communication port group 72 on the basis of the destination port ‘2 ’ in the in-device frame header 81.

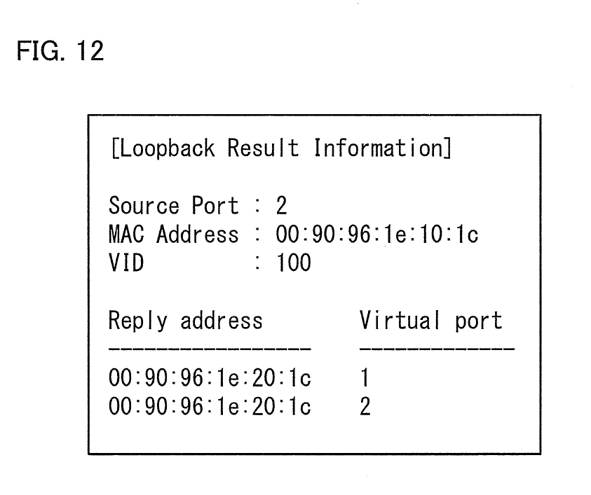

FIG. 12 is a diagram illustrating an exemplary screen obtained as a result of the loopback test 1, which is displayed on a maintenance terminal. In the exemplary screen illustrated in FIG. 12, “Source Port: 2” represents the port 2 of the L2SW 13, which has been set as the start point of the MEP of the LBM. “MAC Address” represents the MAC address of the port 2 of the L2SW 13. “VID: 100” represents a loopback test of the VLAN 100.

“Reply address” represents the MAC address of the port 1 of the L2SW 11 from which the LBR has been returned. “Virtual port” represents which virtual port of the port 1 of the L2SW 11 the LBR has been returned from. That is, in the exemplary screen of FIG. 12, it may be seen that the LBR has been returned from the virtual ports with the in-port logical numbers 1 and 2 of the L2SW 11.

In this way, a virtual port that has received an LBM stores the in-port logical number in the response source logical number of an LBR, and makes a response. Accordingly, even if the L2SW 13 receives a plurality of LBRs from a single port, the L2SW 13 is able to identify the virtual ports and verify the normality of the network.

### Loopback Test 2

It is assumed that a maintenance person performs a multicast loopback test in which the in-port logical number 1 of the port 1 of the L2SW 11 is set as the start point of MEP.

In this case, the setting control unit 73 of the L2SW 11 sets a multicast MAC address in the area of destination MAC address in the frame format 91 illustrated in FIG. 11. In the area of source MAC address, the MAC address of the port 1 of the L2SW 11 is set. In the area of VLAN tag, ‘100 ’ is set. In the area of Ether Type, a value indicating that the frame is an Ether Type for OAM is set. In the area of opcode, ‘0x03 ’ is set because of an LBM. In the area of Transaction-id, an arbitrary value specified by the maintenance person is set. In the area of transmission source logical number, the in-port logical number ‘1 ’ of the port 1 of the L2SW 11 is set. In the area of response source logical number, ‘0 ’ is set because no virtual port is specified as the target by the multicast loopback test. In the area of FCS, data for checking the normality of the frame is set. The setting control unit 73 further sets the port 1 and the in-port logical number 1, which are the MEPs of the transmission source, in the areas of receiving port number and receiving in-port logical number in the in-device frame header 81, respectively. The setting control unit 73 outputs the thus generated LBM to the packet SW unit 74.

The packet SW unit 74 stores the belonging VLAN, the MAC address, the port number, and the in-port logical number in the learning TB 76A on the basis of the received LBM. The packet SW unit 74 refers to the output destination setting TB 75B, and acquires the output destination port of the LBM generated by the setting control unit 73. The packet SW unit 74 generates an output frame destined to the in-port logical number 2 of the port 1 and an output frame destined to the port 2 on the basis of the acquired output destination port. The output frame destined to the in-port logical number 2 of the port 1 is a frame destined to the own port and an MEP has been set in the output destination port (the in-port logical number 2 of the port 1) (see FIG. 7). Therefore, the packet SW unit 74 outputs the output frame destined to the in-port logical number 2 of the port 1 to the setting control unit 73.

The setting control unit 73 generates an LBR on the basis of the output frame received from the packet SW unit 74. The setting control unit 73 generates an LBR in which response source logical number 2 has been set. Further, the setting control unit 73 sets a copy of the transmission source logical number 1 of the received LBM in the area of transmission source logical number of the LBR. The LBR generated by the setting control unit 73 is output to the packet SW unit 74. Since the LBR is a frame destined to the in-port logical number 1 of the port 1 of the own device, the packet SW unit 74 outputs the LBR to the setting control unit 73. The LBR received by the setting control unit 73 has the response source logical number ‘2 ’ set therein. Therefore, the maintenance person can know that a response to the LBM has been made at the virtual port with the in-port logical number 2 of the port 1. That is, the maintenance person is able to verify the normality of the network at a level of the virtual port.

The output frame destined to the port 2 is output from the port 2 of the L2SW 11 and is received at the port 1 of the L2SW 13. In the L2SW 13, it is assumed that an MEP has been set in the port 2. The L2SW 13 generates an LBR in response to the received LBM in a manner similar to that in the Loopback Test 1. At this time, the setting control unit 73 of the L2SW 13 copies and sets the transmission source logical number ‘1 ’ of the received LBM as it is in the area of transmission source logical number of the LBR. That is, when an LBM is transmitted from a virtual port, the L2SW 13 copies and sets the transmission source logical number of the LBM in the area of transmission source logical number of an LBR so that the LBR is correctly returned to the transmission source virtual port. Note that since the port 2 of the L2SW 13 is not a virtual port, the response source logical number of the LBR is ‘0’.

The LBR generated by the L2SW 13 is received at the port 2 of the L2SW 11. When the transmission source logical number of the received LBR is not ‘0 ’, the packet SW unit 74 does not refer to the learning TB 76A, and acquires an in-port logical number to which the LBR is to be output from the transmission source logical number. Thus, the LBR is output to the correct port even if the learning TB 76A has been overwritten due to the loopback test performed by another maintenance person.

Since the transmission source logical number of the received LBR is ‘1 ’, the in-port logical number to which the received LBR is to be output is ‘1 ’. The received LBR is a frame destined to the own port, and an MEP has been set in the output destination port (the in-port logical number 1 of the port 1). Therefore, the packet SW unit 74 outputs the received LBR to the setting control unit 73. The setting control unit 73 compares the Transaction-id of the transmitted LBM with the Transaction-id of the received LBR, and notifies the maintenance terminal 31 of a result thereof.

In this way, the transmission source logical number of the LBM is copied to and set in the area of transmission source logical number of the LBR. The L2SW 11 set as the start point of the MEP refers to the transmission source logical number of the received LBR instead of the learning TB 76A when searching for the output destination port of the received LBR. Thus, even if the content of the learning TB 76A has been changed, the LBR is correctly returned to the start point of the MEP.

### Loopback Test 3

It is assumed that a maintenance person performs a unicast loopback test in which the port 2 of the L2SW 13 to which the VLAN 100 is assigned is set as the start point of MEP and in which the virtual port with the in-port logical number 1 of the port 1 of the L2SW 11 is set as the target.

The setting control unit 73 of the L2SW 13 sets the MAC address of the port 1 of the L2SW 11 in the area of destination MAC address in the frame format 91 illustrated in FIG. 11. In the area of transmission source MAC address, the MAC address Of the port 2 of the L2SW 13 is set. In the area of VLAN tag, ‘100 ’ is set. In the area of Ether Type, a value indicating that the frame is an Ether Type for OAM is set. In the area of opcode, ‘0x03 ’ is set because of an LBM. In the area of Transaction-id, an arbitrary value specified by the maintenance person is set. In the area of transmission source logical number, ‘0 ’ is set because the port 2 of the L2SW 13 is not a virtual port. In the area of response source logical number, ‘1 ’ is set because the virtual port with the in-port logical number 1 of the port 1 of the L2SW 11 is specified as the target by the unicast loopback test. In the area of FCS, data for checking the normality of the frame is set. The L2SW 13 transmits the thus generated LBM to the in-port logical number 1 of the port 1 of the L2SW 11 via unicast.

The LBM transmitted from the L2SW 13 is received at the port 2 of the L2SW 11. When the response source logical number of the received LBM is not ‘0 ’, the packet SW unit 74 does not refer to the learning TB 76A, and acquires an in-port logical number to which an LBR is to be output based on the response source logical number. Thus, the received LBM is output to the correct port even if the learning TB 76A has been overwritten due to the loopback test performed by another maintenance person.

Since the response source logical number of the received LBM is ‘1 ’, the in-port logical number to which the received LBM is to be output is ‘1 ’. The received LBM is a frame destined to the own port, and an MEP has been set in the output destination port (the in-port logical number 1 of the port 1). Therefore, the packet SW unit 74 outputs the received LBM to the setting control unit 73.

The setting control unit 73 generates an LBR on the basis of the received LBM. The setting control unit 73 generates an LBR in which the transmission source logical number ‘0 ’ of the received LBM is copied to and set in the area of transmission source logical number and in which ‘1 ’ is set in the area of response source logical number. The other operation is similar to that explained above, and the generated LBR is output from the port 2 of the L2SW 11 and is received at the port 2 of the L2SW 13.

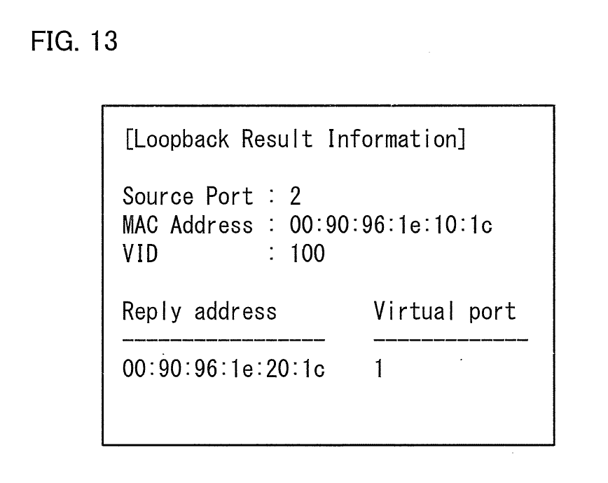

FIG. 13 is a diagram illustrating an exemplary screen obtained as a result of the loopback test 3, which is displayed on a maintenance terminal. In the exemplary screen illustrated in FIG. 13, “Source Port: 2” represents the port 2 of the L2SW 13, which has been set as the start point of the MEP of the LBM. “MAC Address” represents the MAC address of the port 2 of the L2SW 13. “VID: 100” represents a loopback test of the VLAN 100. “Reply address” represents the MAC address of the port 1 of the L2SW 11 from which the LBR has been returned. “Virtual port” represents which virtual port of the port 1 of the L2SW 11 the LBR has been returned from. That is, in the exemplary screen of FIG. 13, it may be seen that the LBR has been returned from the virtual port with the in-port logical number 1 of the L2SW 11 which has been set as the target.

In this way, when a loopback test is performed using a virtual port as the target, the in-port logical number of the target is set in the area of response source logical number of an LBM. When an LBM in which a virtual port is set as the target is received, the target L2SW does not refer to the learning TB 76A, and searches for an output destination port on the basis of the response source logical number. Thus, the LBM is correctly transferred to the target even if the content of the learning TB 76A has been changed. Further, since the LBR includes an in-port logical number of a virtual port, a maintenance person is able to verify the normality of the network at a level of the virtual port.

### Loopback Test 4

It is assumed that a maintenance person performs a unicast loopback test in which the in-port logical number 1 of the port 1 of the L2SW 11 is set as the start point of MEP and in which the port 2 of the L2SW 13 is set as the target.

The setting control unit 73 of the L2SW 11 sets the MAC address of the port 2 of the L2SW 13 in the area of destination MAC address in the frame format 91 illustrated in FIG. 11. In the area of source MAC address, the MAC address of the port 1 of the L2SW 11 is set. In the area of VLAN tag, ‘100 ’ is set. In the area of Ether Type, a value indicating that the frame is an Ether Type for OAM is set. In the area of opcode, ‘0x03 ’ is set because of an LBM. In the area of Transaction-id, an arbitrary value specified by the maintenance person is set. In the area of transmission source logical number, the in-port logical number ‘1 ’ of the port 1 of the L2SW 11 is set. In the area of response source logical number, ‘0 ’ is set because no virtual port is specified as the target. In the area of FCS, data for checking the normality of the frame is set. The setting control unit 73 outputs the generated LBM to the packet SW unit 74.

The packet SW unit 74 refers to the learning TB 76A when the MAC address of the transfer destination has been learned, or refers to the output destination setting TB 75B when not learned, and searches for the output destination port of the LBM. The LBM is output from the found output destination port.

The LBM transmitted from the L2SW 11 is received at the port 1 of the L2SW 13. The setting control unit 73 of the L2SW 13 generates an LBR on the basis of the received LBM in a manner similar to that described above. The setting control unit 73 of the L2SW 13 generates an LBR in which ‘0 ’ is set in the area of response source logical number and in which the transmission source logical number ‘1’ of the LBM is copied to and set in the area of transmission source logical number. The LBR generated by the L2SW 13 is received at the port 2 of the L2SW 11. Since the transmission source logical number of the received LBR is not ‘0 ’, the packet SW unit 74 does not refer to the learning TB 76A, and acquires an in-port logical number to which the LBR is to be output from the transmission source logical number. Thus, the LBR is output to the correct port even if the learning TB 76A has been overwritten due to the loopback test performed by another maintenance person.

Since the transmission source logical number of the received LBR is ‘1 ’, the in-port logical number to which the received LBR is to be output is ‘1 ’. The received LBR is a frame destined to the own port, and an MEP has been set in the output destination port (the in-port logical number 1 of the port 1). Therefore, the packet SW unit 74 outputs the received LBR to the setting control unit 73. The setting control unit 73 compares the Transaction-id of the transmitted LBM with the Transaction-id of the received LBR, and notifies the maintenance terminal 31 of a result thereof.

In this way, the transmission source logical number of the LBM is copied to and set in the area of transmission source logical number of the LBR. The L2SW 11 set as the start point of the MEP refers to the transmission source logical number of the received LBR instead of the learning TB 76A when searching for the output destination port of the received LBR. Thus, even if the content of the learning TB 76A has been changed, the LBR is correctly returned to the start point of the MEP.

The operation of the packet SW unit 74 will be explained using a flowchart.

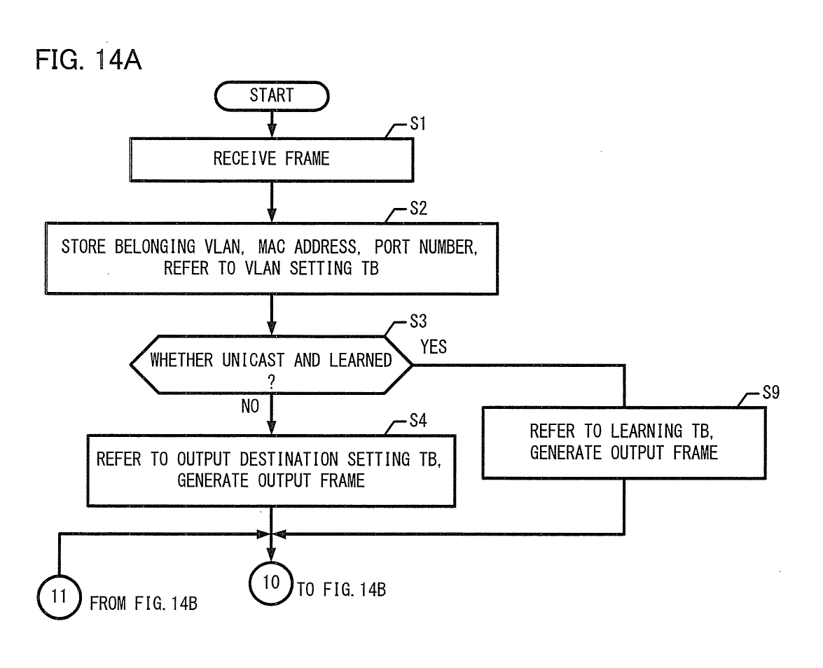

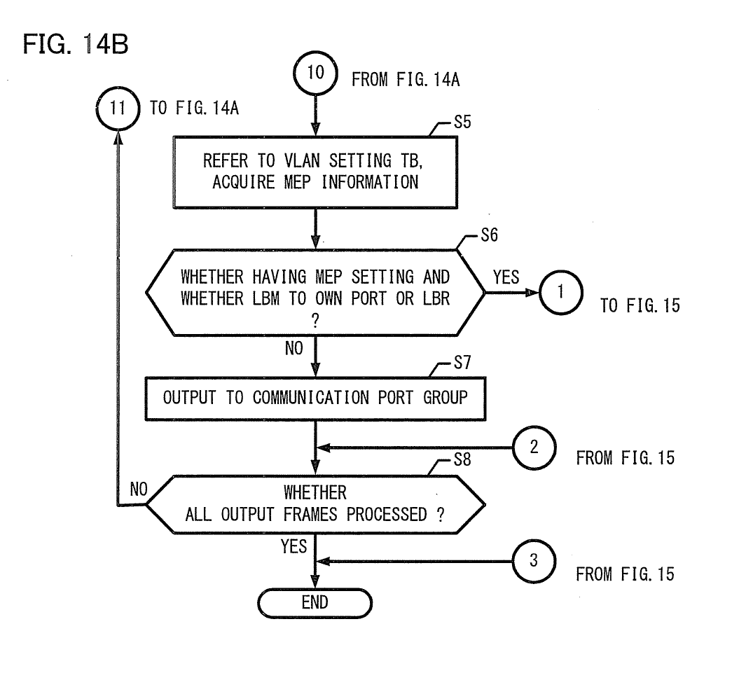

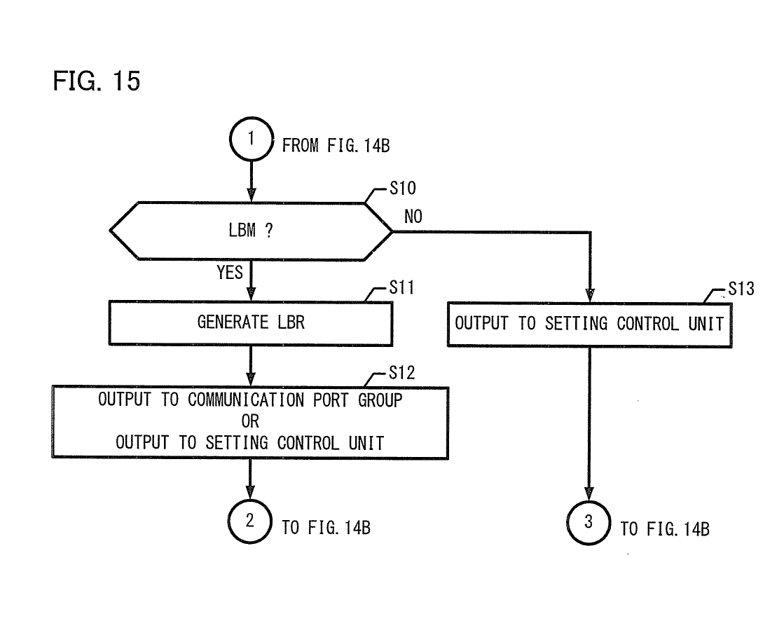

FIGS. 14A to 14B, and 15 are flowcharts illustrating the operation of the packet SW unit 74. A frame received at the communication port group 72 is added with the in-device frame header 81. In the area of receiving port number in the in-device frame header 81, the port number where the frame has been received is set. In the area of receiving in-port logical number, the in-port logical number of the virtual port where the frame has been received is set. The frame with the in-device frame header 81 added thereto in this manner is output to the packet SW unit 74.

In step S1, the packet SW unit 74 receives a frame from the communication port group 72 or the setting control unit 73.

In step S2, the packet SW unit 74 stores the belonging VLAN and the MAC address of the received frame and the port number of the port where the frame has been received in the learning TB 76A. When a virtual port is set in the port where the frame has been received, the packet SW unit 74 also stores the in-port logical number of the virtual port. Further, the packet SW unit 74 refers to the VLAN setting TB 75A on the basis of the port number of the port where the frame has been received, and searches for the presence of the section corresponding to the VID of the received frame. When the section corresponding to the VID is not present, the packet SW unit 74 determines that the received frame is not a frame to be received at this port, and discards the received frame. Note that the packet SW unit 74 determines in step S2 that the section corresponding to the VID is present, and proceeds to step S3.

In step S3, the packet SW unit 74 determines whether or not the transmission destination of the received frame is unicast and has been learned in the learning TB 76A. When the transmission destination of the received frame is unicast and has been learned, the packet SW unit 74 proceeds to step S9. When the transmission destination of the received frame is not unicast or has not been learned, the packet SW unit 74 proceeds to step S4. That is, when the received frame is multicast or when the transmission destination has not been learned, the packet SW unit 74 proceeds to step S4.

In step S4, the packet SW unit 74 refers to the output destination setting TB 75b, and acquires the port number and the in-port logical number of the virtual port corresponding to the VID of the received frame. The packet SW unit 74 sets the acquired port number and in-port logical number in the areas of destination port number and the destination in-port logical number in the in-device frame header 81, and generates an output frame.

In step S5, the packet SW unit 74 refers to the VLAN setting TB 75A on the basis of the destination port number and destination in-port logical number of the generated output frame, and acquires MEP information about the destination port to which the output frame is output.

In step S6, the packet SW unit 74 determines whether the destination port has an MEP setting and whether the output frame is an LBM destined to the own port or an LBR. When the destination port has an MEP setting and when the output frame is an LBM destined to the own port or an LBR, the packet SW unit 74 proceeds to step S10. When the destination port has no MEP setting or when the output frame is not an LBM destined to the own port or an LBR, the packet SW unit 74 proceeds to step S7.

In step S7, the packet SW unit 74 sets a VLAN tag (VID) in the output frame in accordance with the port type of the output destination port, and outputs the output frame to the communication port group 72.

In step S8, the packet SW unit 74 determines whether all output frames have been processed. When all output frames have been processed, the packet SW unit 74 ends the process of FIGS. 14A to 14B. When all output frames have not been processed, the packet SW unit 74 proceeds to step S5.

In step S9, the packet SW unit 74 refers to the learning TB 76A on the basis of the destination MAC address of the received frame, and acquires a port number and in-port logical number to which the received frame is transferred. The packet SW unit 74 sets the acquired port number and in-port logical number in the areas of destination port number and destination in-port logical number in the in-device frame header 81 so as to generate an output frame.

Note that when the received frame is an LBR and the transmission source logical number thereof is not ‘0 ’, the packet SW unit 74 does not refer to the learning TB 76A, but sets the transmission source logical number of the received LBR in the area of destination in-port logical number in the in-device frame header 81 so as to generate an output frame. Further, when the received frame is an LBM and the response source logical number thereof is not ‘0 ’, the packet SW unit 74 does not refer to the learning TB 76A, but sets the response source logical number of the received LBM in the area of destination in-port logical number in the in-device frame header 81 so as to generate an output frame.

In step S10, the packet SW unit 74 determines whether or not the output frame is an LBM. When the output frame is not a non-LBM, that is, the output frame is an LBR, the packet SW unit 74 proceeds to step S13. When the output frame is an LBM, the packet SW unit 74 proceeds to step S11.

In step S11, the packet SW unit 74 outputs the output frame (the output frame of the received LBM) to the setting control unit 73. The setting control unit 73 generates an LBR on the basis of the output frame. At this time, the setting control unit 73 copies and sets the receiving port number and receiving in-pot logical number of the output frame received from the packet SW unit 74 in the areas of destination port number and destination in-port logical number in the in-device frame header 81. The setting control unit 73 outputs the generated LBR to the packet SW unit 74.

In step S12, the packet SW unit 74 outputs the output frame (LBR) output from the setting control unit 73 to the communication port group 72. Note that when the output destination of the output frame is a port in the own device, that is, when the LBM has been transmitted from a port of the own device, the packet SW unit 74 outputs the output frame to the setting control unit 73. The setting control unit 73 notifies the maintenance terminal 31 of a result of comparison between the Transaction-id of the LBM and the Transaction-id of the LBR.

In step S13, the packet SW unit 74 outputs the output frame to the setting control unit 73. The setting control unit 73 notifies the maintenance terminal 31 of a result of comparison between the Transaction-id of the LBM and the Transaction-id of the LBR.

In this way, a transmission source logical number and a response source logical number are set in a frame of an LBM and an LBR, thus allowing a maintenance person to correctly check the normality and abnormality of a network at a level of the virtual port.

Note that the area of transmission source logical number of a frame of an LBM and an LBR is not necessary when the port set as the start point of MEP is not a virtual port. For example, in the test examples of the loopback test 1 and loopback test 3 explained above, the area of transmission source logical number of a frame of an LBM and an LBR is not necessary. In this case, the frame length of the LBM and the LBR are reduced, and the transfer time of the frame is reduced.

In the foregoing, furthermore, an L2SW notifies the maintenance terminal 31 of a result of comparison between the Transaction-id of the LBM and the Transaction-id of the LBR. However, an L2SW may transmit the Transaction-id of the LBR to the maintenance terminal 31 and the maintenance terminal 31 may compare the Transaction-id of the LBM with the Transaction-id of the LBR.

Furthermore, instead of the transmission source logical number and the in-port logical number of the response source logical number, a VID corresponding to the in-port logical number may be used. The reason is that, as illustrated in FIG. 7, in-port logical numbers correspond to VIDs in one-to-one correspondence, and an in-port logical number is derived from a VID.

### Second Embodiment

Next, a second embodiment will be explained in detail with reference to the drawings.

In the first embodiment, the direction in which an LBM and LBR are transmitted is inside an L2SW as viewed from an MEP. For example, in the loopback test 1 of the first embodiment, an LBM is transmitted to the inside of the L2SW 13 such as from the port 2 of the L2SW 13 to the port 1 of the L2SW 13. An LBR is transmitted to the inside of the L2SW 11 such as from the port 1 of the L2SW 11 to the port 2 of the L2SW 11.

In the second embodiment, an explanation will be given of a case where the direction in which an LBM and LBR are transmitted is outside an L2SW as viewed from an MEP.

For example, an explanation will be given of a case where a loopback test in which the port 1 of the VLAN 100 of the L2SW 13 illustrated in FIG. 5 is set as the start point of MEP and in which the port 2 of the L2SW 11 is set as the target is performed.

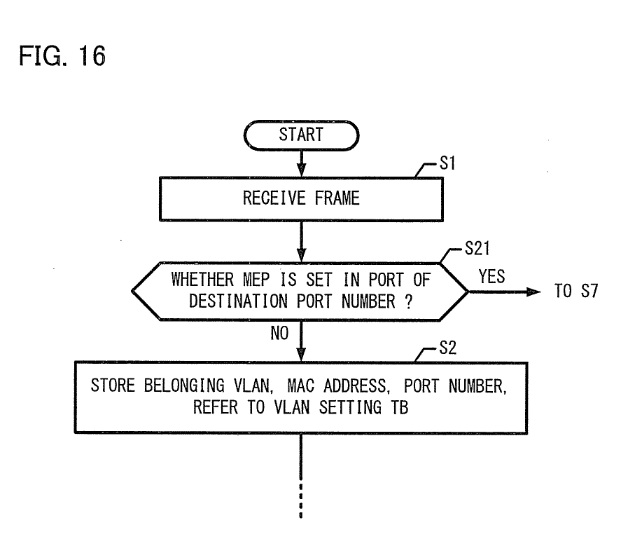

FIG. 16 is a first flowchart illustrating the operation of a packet SW unit according to the second embodiment. The processing of steps S1 and S2 illustrated in FIG. 16 is similar to that of steps S1 and S2 of FIGS. 14A to 14B, and explanations thereof are omitted. Further, the processing of the other steps is similar to that of FIGS. 14A to 14B, and 15, and is not illustrated in the figure.

In step S21, the setting control unit 73 of the L2SW 13 generates an LBM in accordance with an instruction of a maintenance person, sets the port 1 in the area of destination port number in the in-device frame header 81, and outputs the LBM to the packet SW unit 74.

The packet SW unit 74 of the L2SW 13 refers to the VLAN setting TB 75A, and determines whether an MEP has been set in the port having the destination port number in the in-device frame header 81. When an MEP has been set in the port having the destination port number in the in-device frame header 81, the packet SW unit 74 proceeds to step S7. For example, when an MEP has been set in the destination port number 1 (the port 1 of the L2SW 13) in the in-device frame header 81, the LBM is output from the port 1. On the other hand, when no MEP has been set in the port having the destination port number in the in-device frame header 81, the packet SW unit 74 proceeds to step 2.

Note that when a virtual port has been set as the start point of MEP, the setting control unit 73 sets the in-port logical number of the virtual port in the area of destination in-port logical number in the in-device frame header 81.

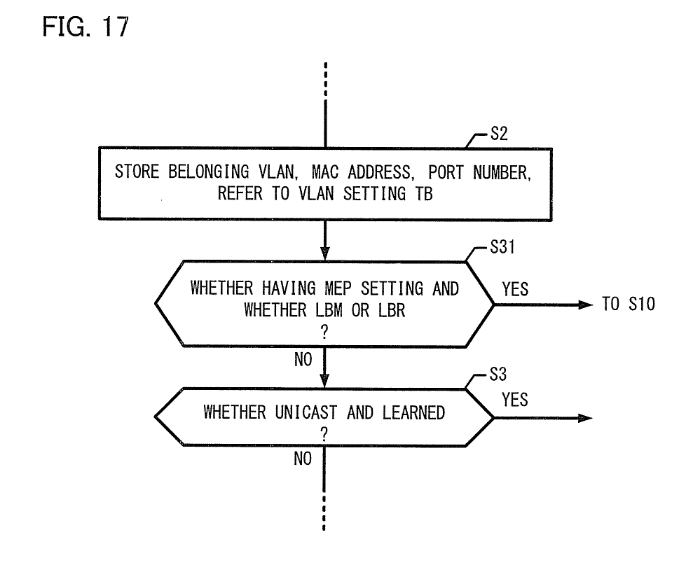

FIG. 17 is a second flowchart illustrating the operation of a packet SW unit according to the second embodiment. The processing of steps S2 and S3 illustrated in FIG. 17 is similar to that of steps S2 and S3 of FIGS. 14A to 14B, and explanations thereof are omitted. Further, the processing of the other steps is similar to that of FIGS. 14A to 14B, and 15, and is not illustrated in the figure.

In step S31, the packet SW unit 74 of the L2SW 11 refers to the VLAN setting TB 75A, and determines whether the receiving port (also including a virtual port) where the frame has been received has an MEP setting and whether the received frame is an LBM or an LBR. When the receiving port where the frame has been received has an MEP setting and when the received frame is an LBM or an LBR, the packet SW unit 74 proceeds to step S10. For example, when an MEP has been set in the port 2 of the L2SW 11, the packet SW unit 74 proceeds to step S10, and generates an LBR. On the other hand, when no MEP has been set in the receiving port where the frame has been received or the received frame is not an LBM or an LBR, the packet SW unit 74 proceeds to step S3.

Note that when the port 1 of the L2SW 13 receives an LBR from the port 2 of the L2SW 11, it is regarded that the receiving port 1 has an MEP setting and that an LBR destined to the own port has been received. Thus, the packet SW unit 74 of the L2SW 13 proceeds to step S10 as a result of the determination of step S31, and outputs the received LBR to the setting control unit 73.

In this way, regardless of whether the direction in which an LBM or an LBR is transmitted is outside or inside an L2SW as viewed from an MEP, a correct loopback test is performed.

And, the communication device and loopback testing method disclosed above allow a maintenance person to correctly verify the normality of a network.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A communication device operable to verify normality of a network by a loopback test, the communication device comprising:
a plurality of ports used to connect to a physical link included in the network; and
an identification information addition part to add virtual port information used to identify a virtual port to a reply frame when receiving a message frame to the virtual port set on the physical link, the message frame being used to verify normality of the network by the loopback test, and replying the reply frame in which the virtual port information is added, to a communication device that has transmitted the message frame.

2. The communication device according to claim 1, wherein information of a port from where the message frame is transmitted is added in the message frame.

3. The communication device according to claim 2, wherein the identification addition part adds the port information added in the message frame to the reply frame.

4. The communication device according to claim 3, wherein the information of the port includes information used to identify the virtual port.

5. The communication device according to claim 1, wherein a transmitting of the reply frame is applicable in the direction of one of inside and outside at the communication device as viewed from the virtual port at which the reply frame is transmitted.

6. A communication device operable to verify normality of a network by a loopback test, the communication device comprising:
a plurality of ports used to connect to a physical link included in the network; and
an identification information addition part to add virtual port information used to identify a virtual port to a message frame used to verify normality of the network by the loopback test when transmitting the message frame from a virtual port set on the physical link.

7. The communication device according to claim 6, further comprising:
a reply frame reception part for receiving a reply frame in which the virtual port information is added, the reply frame being transmitted from the communication device receiving the message frame.

8. The communication device according to claim 7, further comprising:
a frame forwarding part for forwarding the reply frame to the virtual port at which the message frame is transmitted based on the virtual port information added in the reply frame.

9. The communication device according to claim 6, wherein the identification information addition part adds information indicating a virtual port from where the reply frame is replied, in the communication device receiving the message frame.

10. The communication device according to claim 6, wherein a transmitting of the message frame is applicable in the direction of one of inside and outside at the communication device as viewed from the virtual port at which the message frame is transmitted.

11. A loopback testing method of a communication device operable to verify normality of a network by a loopback test, the loopback testing method comprising:
receiving a message frame to a virtual port set on a physical link, the message frame being used to verify normality of the network by the loopback test;
adding virtual port information used to identify a virtual port to a reply frame; and
replying the reply frame in which the virtual port information is added, to the communication device transmitting the message frame.

12. The loopback testing method according to claim 11, in a case where the communication device transmits a message frame, further comprising:
adding the virtual port information to the message frame; and
transmitting the message frame in which the virtual port information is added, from the virtual port set on the physical link.
